(19) United States
(12) Patent Application Publication
(10) Pub. No.: US 2010/0044212 A1
(43) Pub. Date: Feb. 25, 2010

(54) VERTICALLY STANDING IONIC POLYMER-METAL COMPOSITE

(75) Inventors: Yong Hyup Kim, Seoul (KR); Seong Jun Kim, Seoul (KR)

Correspondence Address: KNOBBE MARTENS OLSON & BEAR LLP, 2040 MAIN STREET, FOURTEENTH FLOOR, IRVINE, CA, 92614, US

(73) Assignee: SNU R&DB Foundation, Seoul (KR)

(21) Appl. No.: 12/196,148

(22) Filed: Aug. 21, 2008

(51) Int. Cl. C25D 21/12; C23C 14/34; B05D 5/12

(52) U.S. Cl. 204/192.12; 378/34; 204/192.34; 427/123; 204/228.1

(57) ABSTRACT

A vertically standing IPMC includes a substrate, a first electrode positioned substantially vertical with respect to an upper surface of the substrate, a second electrode positioned substantially vertical with respect to the upper surface of the substrate and disposed opposite to the first electrode, and an ionic polymer film interposed between the first electrode and the second electrode and standing substantially vertical with respect to the upper surface of the substrate.

### TECHNICAL FIELD

The described technology relates generally to a vertically standing ionic polymer-metal composite (IPMC).

### BACKGROUND

An ionic polymer-metal composite (IPMC) was first proposed by the Oguro group in 1992, and is one of the promising electroactive polymers (EAPs). Typically, an IPMC has electrodes, a composite of a fluorine-substituted ionic polymer film, for example, a Nafion film (i.e., a perfluorosulfonate ionomer manufactured by DuPont), and platinum electrodes disposed on both surfaces of the Nafion film. When the IPMC is used as an actuator and a voltage is applied to the electrodes, the potential difference between the electrodes cause the ionic polymer film of the IPMC to bend due to an electro-osmosis phenomenon. The IPMC may also be used as a sensor. When it is used as a sensor, and an external mechanical stimulus is provided to the IPMC, internal charges are redistributed, so that an electrical signal that can be externally measured is generated. As a result, properties of the external mechanical stimulus such as, by way of example, force, pressure, displacement, velocity, etc. can be quantitatively measured.

Recently, a micromanipulation technique has been drawing increased attention and research into microscale IPMCs, which are smaller than conventional macroscale IPMCs, is actively progressing. FIG. 1 is a schematic diagram illustrating a conventional micro-IPMC. Zhou, et al., Proc. of SPIE Vol. 4936, pp. 154-158, 2002, discloses a micro-IPMC including a substrate 100, a chromium layer 110 formed on the substrate 100 as a bonding layer, gold electrodes 120a and 120b formed on the chromium layer 110, and Nafion 130 interposed between the electrodes 120a and 120b. The microscale IPMC actuator and sensor are in the shape of a horizontal cantilever. While a structure having the shape of the horizontal cantilever can be easily fabricated, the structure limits its applications in the field of actuators or sensors.

### SUMMARY

In one embodiment a vertically standing ionic polymer-metal composite (IPMC) is provided. The IPMC includes a substrate, a first electrode positioned substantially vertical with respect to an upper surface of the substrate, a second electrode positioned substantially vertical with respect to the upper surface of the substrate and disposed to face the first electrode, and an ionic polymer film interposed between the first electrode and the second electrode and positioned substantially vertical with respect to the upper surface of the substrate.

In another embodiment, a method of fabricating a vertically standing IPMC is provided.

The Summary is provided to introduce a selection of concepts in a simplified form that are further described below in the Detailed Description. The Summary is not intended to identity key features or essential features of the claimed subject matter, nor is it intended to be used as an aid in determining the scope of the claimed subject matter.

### BRIEF DESCRIPTION OF THE DRAWINGS

FIG. 1 is a schematic diagram illustrating a conventional micro-ionic polymer-metal composite (IPMC).

FIG. 2 is a schematic perspective view of an illustrative embodiment of a vertically standing IPMC.

FIG. 3 is a schematic cross-sectional view of an illustrative embodiment of a vertically standing IPMC before and after it is bent.

FIG. 4 is a flowchart of an illustrative embodiment of a method for fabricating a vertically standing IPMC.

FIGS. 5 to 14 are schematic diagrams of illustrative embodiments of a method for fabricating a vertically standing IPMC described in FIG. 4.

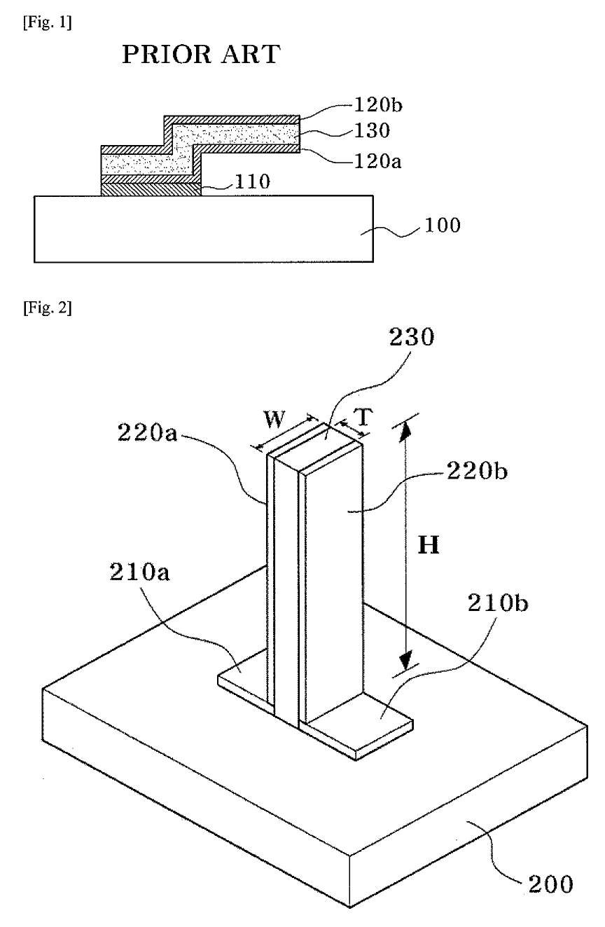

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes made be made, without departing from the spirit or scope of the subject matter presented here. It will be readily understood that the components of the present disclosure, as generally described herein, and illustrated in the Figures, can be arranged, substituted, combined, and designed in a wide variety of different configurations, all of which are explicitly contemplated and make part of this disclosure.

It will also be understood that when an element or layer is referred to as being “on,” or “connected to” another element or layer, the element or layer may be directly on or connected to the other element or layer or intervening elements or layers may be present. As used herein, the term “and/or” may include any and all combinations of one or more of the associated listed items.

FIG. 2 is a schematic perspective view of an illustrative embodiment of a vertically standing ionic polymer-metal composite (IPMC). As illustrated, the vertically standing IPMC includes a substrate 200, a first conductive support unit 210a, a second conductive support unit 210b, a first electrode 220a, a second electrode 220b, and an ionic polymer film 230.

Various kinds of substrates may be used as the substrate 200. For example, the substrate 200 may be a substrate having an insulating layer formed on a conductive substrate. The conductive substrate may include a metal or a semiconductor. The substrate 200 may be an insulating substrate including glass, plastic, polymer, oxide, nitride, etc.

The first conductive support unit 210a and the second conductive support unit 210b are disposed on the substrate 200. The first conductive support unit 210a and the second conductive support unit 210b are electrically connected to the electrodes 220a and 220b of the IPMC, respectively, on an upper surface of the substrate 200. The first conductive support unit 210a and the second conductive support unit 210b function to support the electrodes 220a and 220b so that the electrodes 220a and 220b stand vertically. Stated another way, the first conductive support unit 210a and the second conductive support unit 210b function to position the electrodes 220a and 220b, respectively, substantially vertically on the upper surface of substrate 200. The first conductive support unit 210a and the second conductive support unit 210b may be formed of a metal or a metal alloy. For example, the first conductive support unit 210a and the second conductive support unit 210b may be formed of Au, Ag, Cu, Fe, Co, Ni, Ta, W, Ti, Pt, Pd, TiN, or combinations thereof.

As illustrated, the first electrode 220a is disposed to face the second electrode 220b. One end of the first electrode 220a is electrically connected to the first conductive support unit 210a, and the first electrode 220a stands substantially vertical with respect to the upper surface of the substrate 200. The description of an element “standing substantially vertical with respect to the upper surface of the substrate” used herein means that the element stands or is positioned nearly or exactly perpendicular to the upper surface of the substrate, rather than inclined or parallel with respect to the substrate. One end of the second electrode 220b is electrically connected to the second conductive support unit 210b, and the second electrode 220b stands substantially vertical with respect to the upper surface of the substrate 200. The first electrode 220a and the second electrode 220b may be formed of a metal or a metal alloy. For example, the first electrode 220a and the second electrode 220b may be formed of Au, Ag, Cu, Fe, Co, Ni, Ta, W, Ti, Pt, Pd, TiN, or combinations thereof.

The ionic polymer film 230 is interposed between the first electrode 220a and the second electrode 220b facing the first electrode 220a. That is, the ionic polymer film 230 stands substantially vertical with respect to the upper surface of the substrate 200, and the electrodes 220a and 220b are attached to opposite surfaces of the ionic polymer film 230, as is illustrated in FIG. 2. The ionic polymer film 230 is made of a polymer material having ion exchange ability. For example, the polymer material may include a fluorocarbon-based polymer having an ionic group or a styrene-divinylbenzene polymer having an ionic group. A side group attached to a main chain of the polymer may have an ionic end group such as a sulfonate group (SO₃⁻) or a carboxylate group (COO⁻). A polymer backbone may determine mechanical power, and the hydrophilic side group may provide an ionic group interacting with water and provide a pathway for appropriate ions. Examples of the fluorocarbon-based polymer may include a perfluorosulfonic acid polymer such as Nafion (manufactured by DuPont) or a perfluorocarboxylic acid polymer such as Flemion (manufactured by Asahi Glass Co., Ltd.). In one embodiment, when a voltage is applied between the electrodes 220a and 220b, an electro-osmosis phenomenon may cause the ionic polymer film 230 to bend. The size of the ionic polymer metal composition may be determined based on the height (H), thickness (T), and width (W) of the ionic polymer film 230. At least one of the height (H), thickness (T), and width (W) of the ionic polymer film 230 may be 1 mm or smaller. For example, the height (H) may be about 10 μm to about 1 mm, the width (W) may be about 1 μm to about 500 μm, and the thickness (T) may be about 100 nm to about 10 μm. The aforementioned numeric measurements are only illustrative examples and not to be construed as limiting the scope thereof.

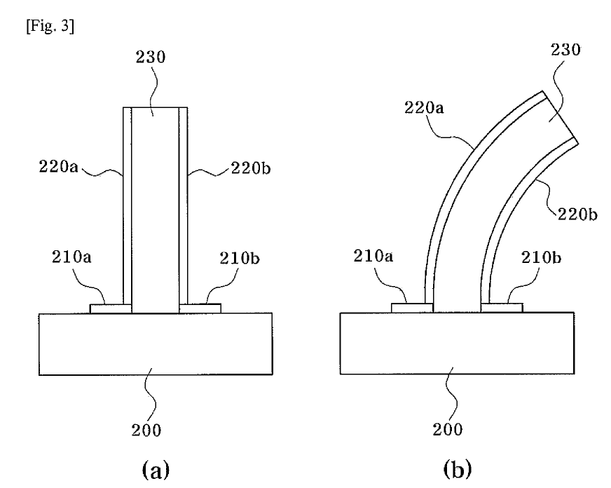

FIG. 3 is a schematic cross-sectional view of an illustrative embodiment of a vertically standing IPMC before and after the vertically standing IPMC is bent. Part (a) of FIG. 3 illustrates the vertically standing IPMC before the vertically standing IPMC is bent, and part (b) of FIG. 3 illustrates the vertically standing IPMC in a bent position.

In one embodiment, when a voltage is applied to the first electrode 220a and the second electrode 220b, an IPMC as an actuator is bent toward the second electrode 220b that is an anode. In another embodiment, when an IPMC is used as a sensor, the IPMC is bent by an external mechanical stimulus, so that a voltage difference between the first electrode 220a and the second electrode 220b of the IPMC generates an electrical signal.

According to one embodiment, the ionic polymer film 230 in the IPMC may stand vertically with respect to the substrate 200. In this position, there is almost no limit to the bending displacement of the ionic polymer film 230 so that the IPMC may react accurately to an external stimulus such as, for example, an external voltage or an external mechanical stimulus. In addition, a much smaller size and a higher integration density of the IPMC may be achieved on a substrate due to the geometry of the vertically standing structure of the IPMC compared with a conventional horizontal structure. For example, the vertically standing IPMC having a smaller size than that of the conventional horizontal structure may be used as a microactuator for handling cells or may be used as a microsensor for measuring fluid flow in a fluid pipe.

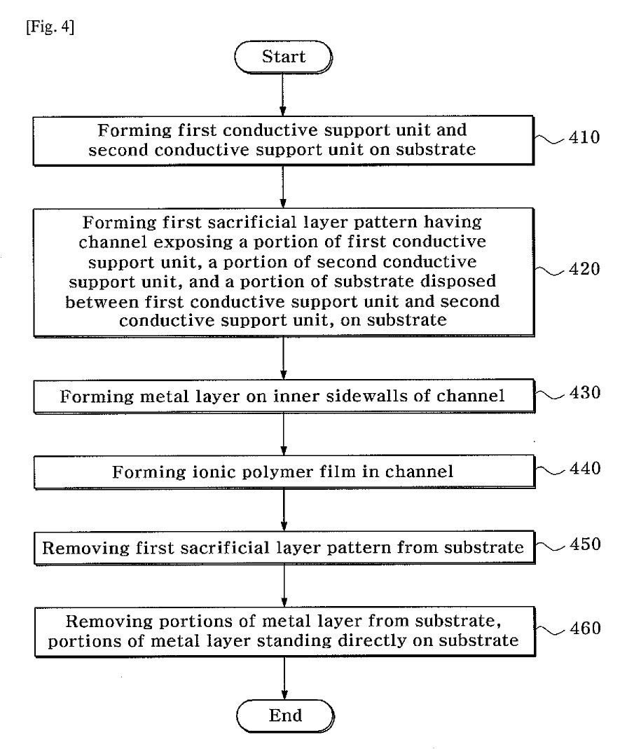

FIG. 4 is a flowchart of an illustrative embodiment of a method for fabricating a vertically standing IPMC. Beginning in block 410, a first conductive support unit and a second conductive support unit are formed on a substrate. In block 420, a first sacrificial layer pattern is formed on the substrate. The first sacrificial layer pattern includes a channel that exposes a portion of the first conductive support unit, a portion of the second conductive support unit, and a portion of the substrate disposed between the first conductive support unit and the second conductive support unit. In block 430, a metal layer is formed on inner sidewalls of the channel. In block 440, an ionic polymer film is formed in the channel. In block 450, the sacrificial layer pattern is removed from the substrate. In block 460, portions of the metal layer standing directly on the substrate are removed. Accordingly, a vertically standing IPMC is produced.

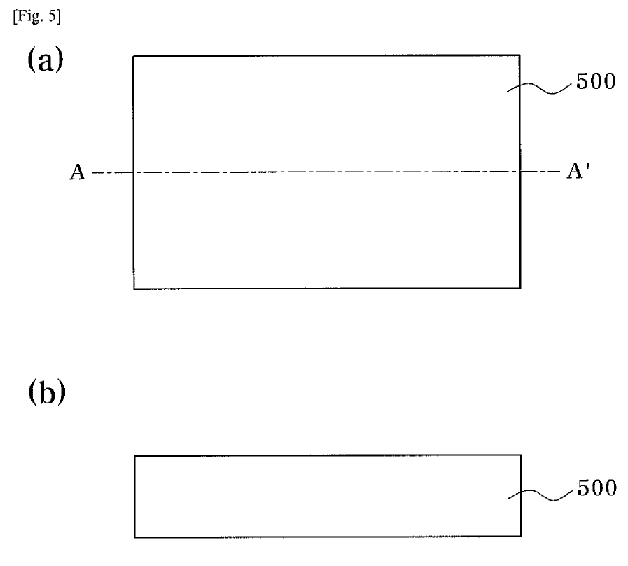

FIGS. 5 to 14 are schematic diagrams of illustrative embodiments of a method for fabricating the vertically standing IPMC described in FIG. 4. In each of FIGS. 5 to 14, a part (a) is a plan view and a part (b) is a cross-sectional view taken from a line A-A′ in the plan view.

Referring to FIG. 5, a substrate 500 is provided. Various kinds of substrates may be used as the substrate 500. For example, the substrate 500 may be a substrate having an insulating layer formed on a conductive substrate. The conductive substrate may include a metal or a semiconductor. The substrate 500 may be an insulating substrate including glass, plastic, oxide, nitride, etc.

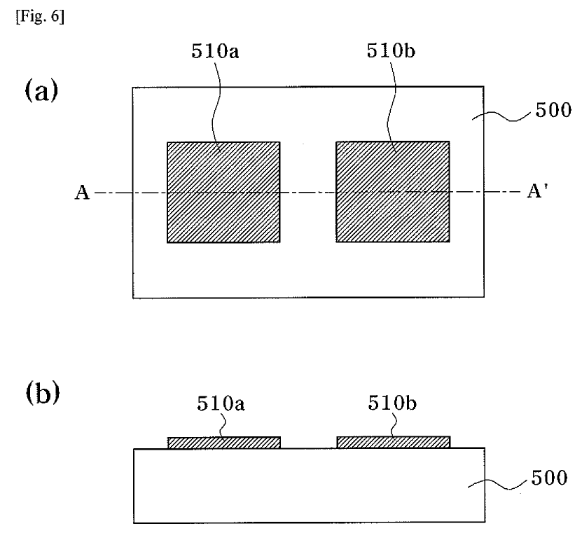

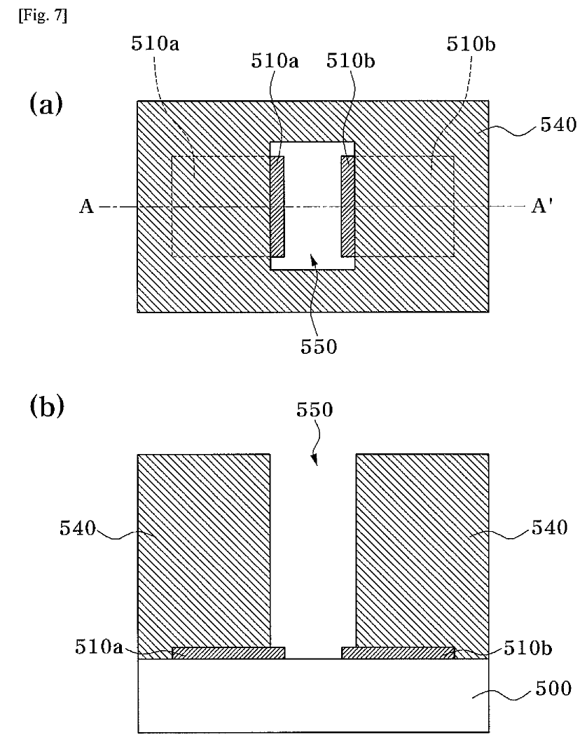

Referring to FIG. 6, a first conductive support unit 510a and a second conductive support unit 510b are formed on the substrate 500. In one embodiment, the first conductive support unit 510a and the second conductive support unit 510b may be formed by forming a conductive material on the substrate 500 using, for example, a sputtering method or an evaporation method, and by patterning the conductive material using a lift-off method. The first conductive support unit 510a and the second conductive support unit 510b may be formed of a metal or a metal alloy.

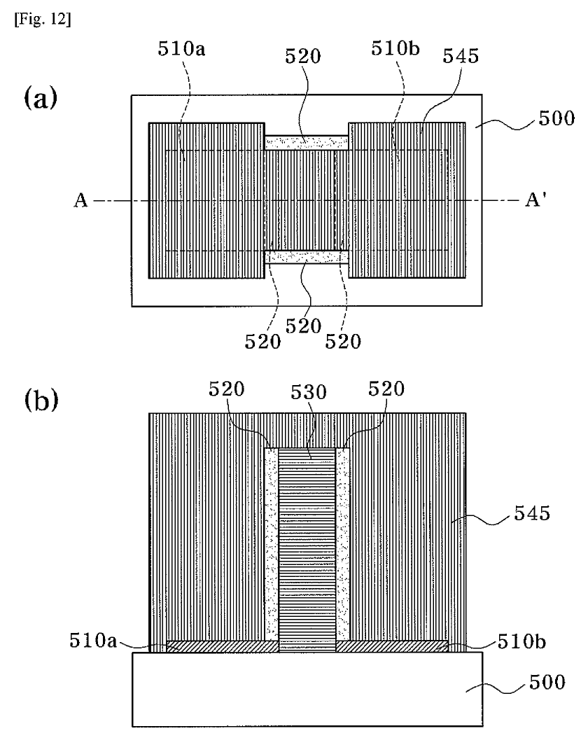

Referring to FIG. 7, a first sacrificial layer pattern 540, which includes a channel 550, is formed on the substrate 500. In one embodiment, the first sacrificial layer pattern 540 may be formed by forming a first sacrificial layer on the substrate 500, and by partially etching the first sacrificial layer to expose a portion of the first conductive support unit 510a, a portion of the second conductive support unit 510b, and a portion of the substrate 500 disposed between the first conductive support unit 510a and the second conductive support unit 510b. As illustrated, the channel 550 is a contact hole of the first sacrificial layer pattern 540. The first sacrificial layer pattern 540 may include a resist material. The resist material may be, for example, polymethyl methacrylate (PMMA) or diazonaphtoquinone (DNQ)/novolak. When the first sacrificial layer is partially etched, for example, a reactive ion etching process or an X-ray lithography process may be performed to form the channel 550 having a high aspect ratio. The depth of the channel 550 may be related to the height of the IPMC. Since the channel 550 is formed in a direction of the depth of the first sacrificial layer pattern 540, the IPMC may stand vertically with respect to the upper surface of the substrate 500. As illustrated, the portions of the support units 510a and 510b at a lower portion of the channel 550 are formed in a manner as to protrude into the channel 550 so that the portions of the support units 510a and 510b may be connected to respective electrodes in the following processes (e.g., a first electrode 520a and a second electrode 520b further described below in conjunction with FIGS. 12-14).

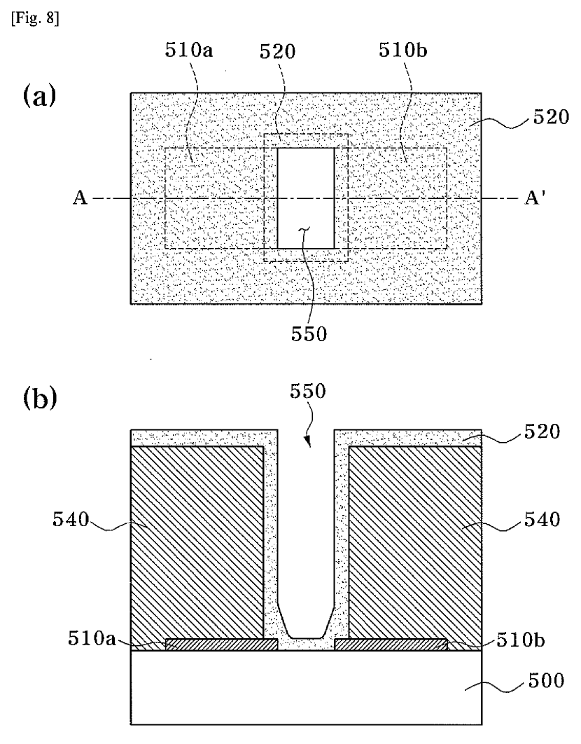

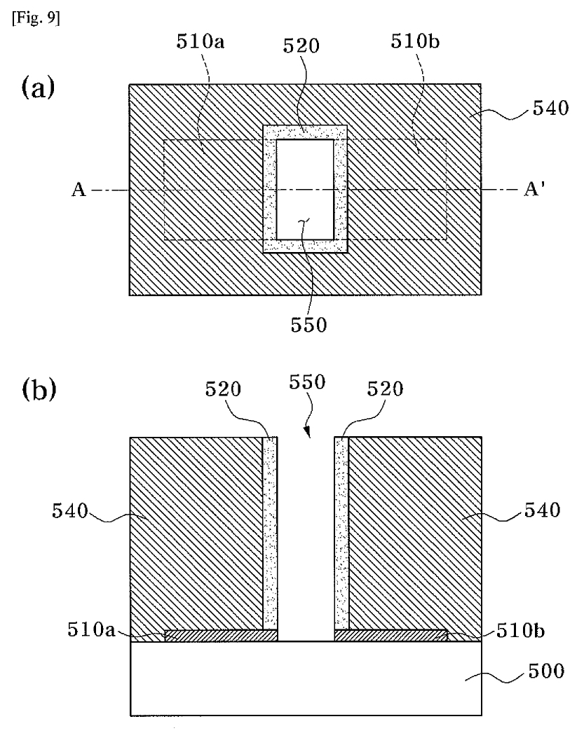

Referring to FIG. 8, a metal layer 520 is formed on the inner sidewalls of the channel 550. The metal layer 520 may be formed by depositing a metal using, for example, a sputtering method, an evaporation method, an electroless plating method, or other suitable deposition method, on the first sacrificial layer pattern 540. The metal layer 520 may be formed substantially vertically with respect to the upper surface of the substrate 500, covering the exposed portions of the first conductive support unit 510a and the second conductive support unit 510b along a circumference of the inner sidewall of the channel 550. Further, the metal layer 520 may be formed on the exposed upper surface of the substrate 500, and on an upper surface of the first sacrificial layer pattern 540.

Referring to FIG. 9, portions of the metal layer 520, formed on the exposed upper surface of the substrate 500 and on the upper surface of the first sacrificial layer pattern 540, are removed. In one embodiment the portions of the metal layer 520 may be removed by an anisotropic etching process. For example, the portion of the metal layer 520 may be removed by an Ar ion bombardment process. As a result of the anisotropic etching process, portions of the metal layer 520 which exist on the inner sidewalls of the channel 550 remain, while the metal layer 520 which existed on the exposed upper surface of the substrate 500 and on the upper surface of the first sacrificial layer pattern 540 are removed.

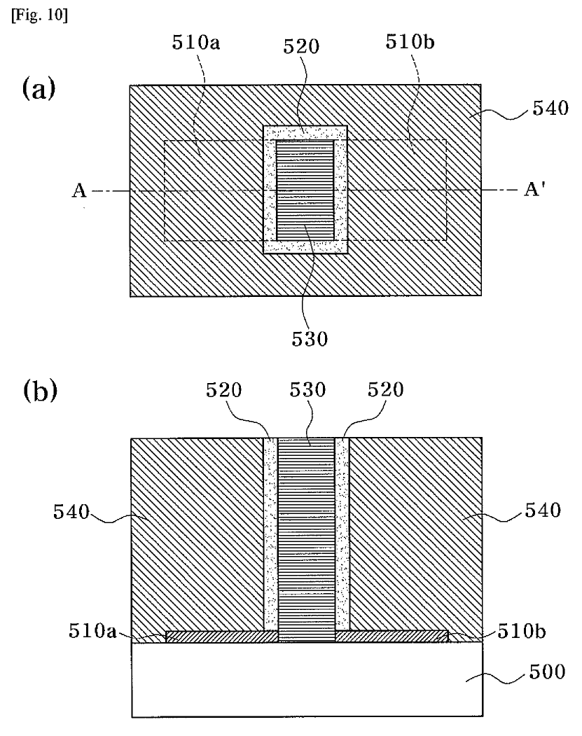

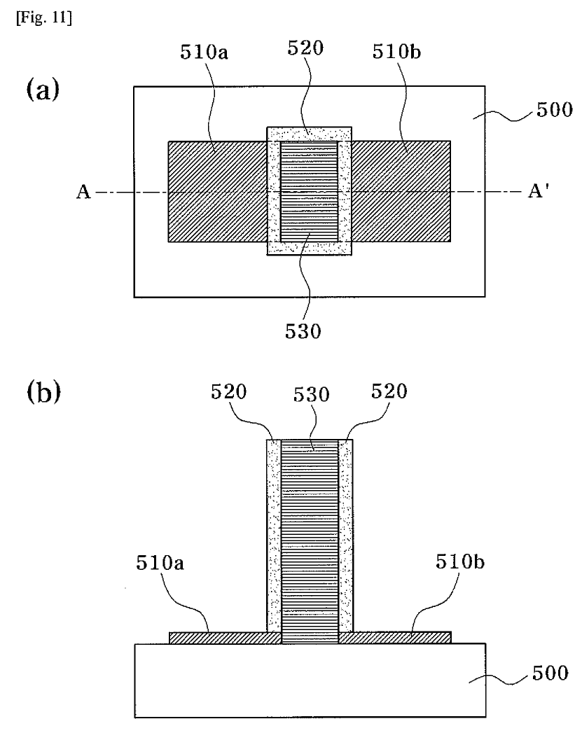

Referring to FIG. 10, an ionic polymer film 530 is formed in the channel 550. The ionic polymer film 530 may be formed by inserting an ionic polymer solution into the channel 550 shown in FIG. 9 and hardening the ionic polymer solution. The ionic polymer solution may be, for example, a Nafion solution.

In one embodiment, the ionic polymer solution may be inserted into the channel 550 by dipping the substrate 500 where the channel 550 is formed into the ionic polymer solution. In another embodiment, the ionic polymer solution may be inserted into the channel 550 by spraying the ionic polymer solution into the substrate 500 where the channel 550 is formed. The inserted ionic polymer solution may be hardened by heating, for example, at a temperature of about 50° C. to 200° C. for 5 to 10 minutes.

Referring to FIG. 11, the first sacrificial layer pattern 540 is removed from the substrate 500. In one embodiment, a wet etching method (e.g. a method using acetone solvent) may be used to remove the first sacrificial layer pattern 540. In another embodiment, a dry etching method (e.g. a method using oxygen plasma) may be used to remove the first sacrificial layer pattern 540.

Referring to FIGS. 12 to 14, portions of the metal layer 520 on or covering the upper surface of the substrate 500 are removed to respectively form a first electrode 520a and a second electrode 520b on the first conductive support unit 51a and the second conductive support unit 510b.

Referring to FIG. 12, a second sacrificial layer pattern 545 is formed to expose the portions of the metal layer 520 on the substrate 500. As illustrated in (a) of FIG. 12, the exposed portions of the metal layer 520 stand directly on the substrate 500. In one embodiment, the second sacrificial layer pattern 545 may be formed by forming a second sacrificial layer on the substrate 500, and by partially etching the second sacrificial layer to expose the portions of the metal layer 520 on the substrate 500. The second sacrificial layer pattern 545 may include a resist material. The resist material may be, for example, polymethyl methacrylate (PMMA) or diazonaphtoquinone (DNQ)/novolak.

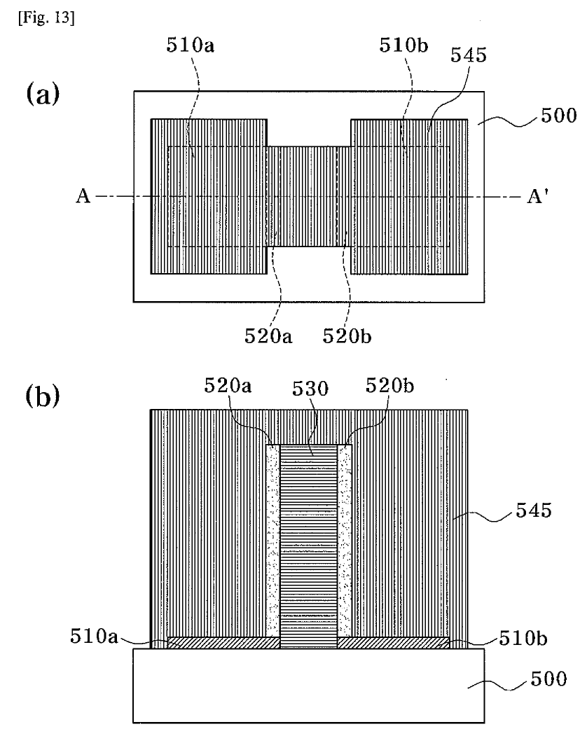

Referring to FIG. 13, the exposed portions of the metal layer 520 depicted, for example, in (a) of FIG. 12 are removed from the substrate 500. In one embodiment, the exposed portions of the metal layer 520 may be removed by a wet etching method using the second sacrificial layer pattern 545 as an etching mask. Accordingly, a first electrode 520a and a second electrode 520b may be formed having the ionic polymer film 530 interposed therebetween.

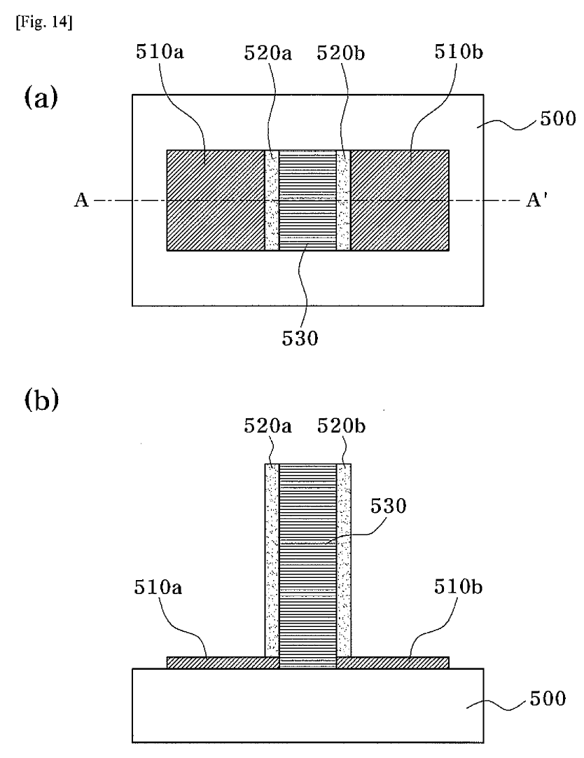

Referring to FIG. 14, the second sacrificial layer 545 is removed to complete the vertically standing IPMC. In one embodiment, a wet etching method (e.g. a method using acetone solvent) may be used to remove the second sacrificial layer pattern 545. In another embodiment, a dry etching method (e.g., a method using oxygen plasma) may be used to remove the second sacrificial layer pattern 545.

According to the above-described method of fabricating an IPMC, a substantially vertically positioned or standing micro-IPMC having high applicability in microactuators and microsensors may be fabricated using a conventional surface micromachining method.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A vertically standing ionic polymer-metal composite (IPMC), comprising:
a substrate;
a first electrode positioned substantially vertical with respect to an upper surface of the substrate;
a second electrode positioned substantially vertical with respect to the upper surface of the substrate and disposed to face the first electrode; and
an ionic polymer film interposed between the first electrode and the second electrode, the ionic polymer film positioned substantially vertical with respect to the upper surface of the substrate.

2. The vertically standing IPMC of claim 1, further comprising:
a first conductive support unit disposed on the substrate, and having one end electrically connected to the first electrode; and
a second conductive support unit disposed on the substrate, and having one end electrically connected to the second electrode.

3. The vertically standing IPMC of claim 2, wherein the first conductive support unit or the second conductive support unit is formed of at least one material selected from the group consisting of Au, Ag, Cu, Fe, Co, Ni, Ta, W, Ti, Pt, Pd, and TiN.

4. The vertically standing IPMC of claim 1, wherein at least one of the height, width and thickness of the ionic polymer film is 1 mm or less.

5. The vertically standing IPMC of claim 1, wherein the ionic polymer film comprises a fluorocarbon-based polymer including an ionic group or a styrene-divinylbenzene polymer including an ionic group.

6. The vertically standing IPMC of claim 5, wherein the ionic group is a sulfonate group or a carboxylate group.

7. The vertically standing IPMC of claim 1, wherein the first electrode is formed of at least one material selected from the group consisting of Au, Ag, Cu, Fe, Co, Ni, Ta, W, Ti, Pt, Pd, and TiN.

8. The vertically standing IPMC of claim 1, wherein the second electrode is formed of at least one material selected from the group consisting of Au, Ag, Cu, Fe, Co, Ni, Ta, W, Ti, Pt, Pd, and TiN.

9. A method of fabricating a vertically standing IPMC, comprising:
forming a first conductive support unit and a second conductive support unit on a substrate;
forming a first sacrificial layer pattern including a channel exposing a portion of the first conductive support unit, a portion of the second conductive support unit, and a portion of the substrate disposed between the first conductive support unit and the second conductive support unit, on the substrate;
forming a metal layer on inner sidewalls of the channel;
forming an ionic polymer film in the channel;
removing the first sacrificial layer pattern from the substrate; and
removing portions of the metal layer from the substrate, the portions of the metal layer standing directly on the substrate.

10. The method of claim 9, wherein the forming of the metal layer comprises:
depositing a metal on the first sacrificial layer; and
removing portions of the metal layer, formed on an upper face of the first sacrificial layer pattern and on the exposed upper surface of the substrate.

11. The method of claim 9, wherein the removing of the portions of the metal layer from the substrate comprises:
forming a second sacrificial layer pattern to expose the portions of the metal layer on the substrate, the portions of the metal layer standing directly on the substrate;
removing the exposed portions of the metal layer from the substrate; and
removing the second sacrificial layer pattern from the substrate.

12. The method of claim 10, wherein the depositing of the metal is performed by a sputtering process, an evaporation process or an electroless plating process.

13. The method of claim 9, wherein the forming of the channel is performed by a reactive ion etching process or an X-ray lithography process.
